(19) United States
(12) Patent Application Publication
(10) Pub. No.: US 2011/0230000 A1
(43) Pub. Date: Sep. 22, 2011

(54) MEMS DEVICE MANUFACTURING METHOD

(75) Inventor: Jun Abatake, Ota-Ku (JP)

(73) Assignee: DISCO CORPORATION, Tokyo (JP)

(21) Appl. No.: 13/048,483

(22) Filed: Mar. 15, 2011

(30) Foreign Application Priority Data
Mar. 16, 2010 (JP) 2010-059383

(51) Int. Cl. H01L 21/02

(52) U.S. Cl. 438/50; 257/E21.002

(57) ABSTRACT

A MEMS device manufacturing method including a break start point forming step of forming a break start point in a substrate along the areas corresponding to a plurality of crossing streets set on the substrate before forming a plurality of MEMS devices on the substrate, a device forming step of forming the MEMS devices in a plurality of areas partitioned by the areas corresponding to the crossing streets on the front side of the substrate after performing the break start point forming step, and a substrate breaking step of applying an external force to the substrate after performing the device forming step to thereby break the substrate along the areas corresponding to the crossing streets where the break start point is formed, thus dividing the substrate into the individual MEMS devices.

### BACKGROUND OF THE INVENTION

1. Field of the Invention

The present invention relates to a manufacturing method for Micro-Electro-Mechanical Systems (MEMS) devices such as acceleration sensors and pressure sensors.

2. Description of the Related Art

In a Micro-Electro-Mechanical Systems (MEMS) device fabrication process, a plurality of crossing division lines called streets are formed on the front side of a substantially disk-shaped substrate such as a glass substrate, silicon substrate, and organic substrate to thereby partition a plurality of areas where MEMS devices such as acceleration sensors, pressure sensors, gyroscopes, and tactile sensors are respectively formed. These areas where the MEMS devices are formed are divided from each other along the streets to thereby obtain the individual MEMS devices. As a dividing apparatus for dividing the substrate having the MEMS devices along the streets, a cutting apparatus called a dicing saw is generally used. This cutting apparatus includes a cutting blade having a thickness of about 40 μm for cutting the substrate having the MEMS devices along the streets. However, in cutting the substrate by using this cutting apparatus, a cutting fluid is supplied to a portion of the substrate to be cut by the cutting blade. Accordingly, there is a problem such that the cutting fluid containing chips may penetrate into a movable portion of each MEMS device formed on the substrate, causing a remarkable reduction in quality of each MEMS device.

As a method of dividing a substrate such as a wafer along the streets, a laser processing method using a pulsed laser beam having an absorption wavelength to the substrate has been proposed in recent years. In this laser processing method, the pulsed laser beam is applied to the substrate along the streets to thereby form laser processed grooves along the streets. By applying an external force to the substrate thus having the laser processed grooves, the substrate is broken along the streets where the laser processed grooves are formed (see Japanese Patent Laid-open No. Hei 10-305420, for example).

### SUMMARY OF THE INVENTION

In the case that a laser beam having an absorption wavelength to the substrate is applied to the substrate having the MEMS devices along the streets as in the wafer dividing method disclosed in Japanese Patent Laid-open No. Hei 10-305420, there is a problem such that debris scattered by the application of the laser beam may be deposited to the surface of each MEMS device and that the quality of each MEMS device may be reduced due to the influence of heat by the laser beam applied to the substrate.

It is therefore an object of the present invention to provide a MEMS device manufacturing method which can manufacture MEMS devices without reducing the quality thereof.

In accordance with an aspect of the present invention, there is provided a MEMS device manufacturing method including a break start point forming step of forming a break start point in a substrate along the areas corresponding to a plurality of crossing streets set on the substrate before forming a plurality of MEMS devices on the substrate; a device forming step of forming the MEMS devices in a plurality of areas partitioned by the areas corresponding to the crossing streets on the front side of the substrate after performing the break start point forming step; and a substrate breaking step of applying an external force to the substrate after performing the device forming step to thereby break the substrate along the areas corresponding to the crossing streets where the break start point is formed, thus dividing the substrate into the individual MEMS devices.

Preferably, the substrate includes a glass substrate. Preferably, the break start point forming step includes the step of applying a laser beam having a transmission wavelength to the substrate along the areas corresponding to the crossing streets in the condition where the focal point of the laser beam is set inside the substrate, thereby forming a plurality of modified layers as the break start point inside the substrate along the areas corresponding to the crossing streets.

According to the present invention, the break start point forming step is performed to form the break start point in the substrate along the areas corresponding to the crossing streets before forming the MEMS devices on the substrate. Accordingly, it is possible to eliminate the problem that the quality of the MEMS devices may be reduced due to the debris scattered or the influence of heat by the application of a laser beam. In the break start point forming step, the break start point is formed in the areas corresponding to the crossing streets set on the substrate before performing the device forming step and the substrate breaking step. Accordingly, in the substrate breaking step, the substrate having the MEMS devices on the front side can be easily divided into the individual MEMS devices by applying an external force to the substrate.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a substrate in the condition where a plurality of MEMS devices have not yet been formed thereon;

FIG. 2 is a perspective view of an essential part of a laser processing apparatus for performing a break start point forming step in the MEMS device manufacturing method according to the present invention;

FIGS. 3A and 3B are sectional side views for illustrating a preferred embodiment of the break start point forming step;

FIG. 4 is a perspective view of the substrate obtained by performing the break start point forming step shown in FIGS. 3A and 3B;

FIGS. 5A and 5B are sectional side views for illustrating another preferred embodiment of the break start point forming step;

FIG. 6 is a perspective view of the substrate obtained by performing the break start point forming step shown in FIGS. 5A and 5B;

FIG. 7 is a perspective view of the substrate obtained by performing a device forming step in the MEMS device manufacturing method according to the present invention;

FIG. 8 is a perspective view of the substrate shown in FIG. 7 in the condition where the substrate is attached to a dicing tape supported to an annular frame;

FIG. 9 is a perspective view of a tape expanding apparatus for performing a substrate breaking step in the MEMS device manufacturing method according to the present invention;

FIGS. 10A to 10C are sectional side views for illustrating the substrate breaking step; and

FIG. 11 is a perspective view of a MEMS device manufactured by the MEMS device manufacturing method according to the present invention.

### DETAILED DESCRIPTION OF THE PREFERRED EMBODIMENTS

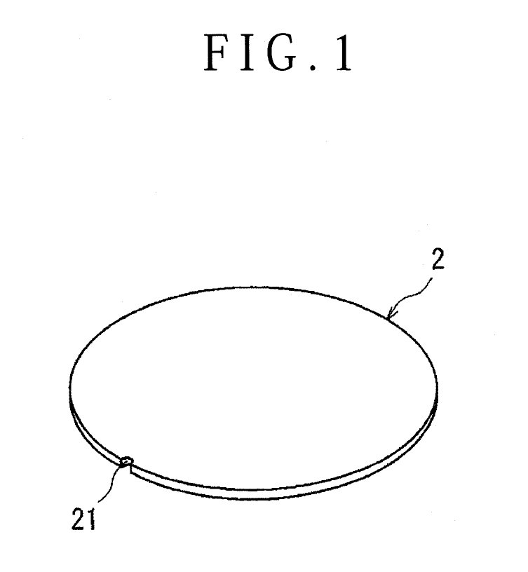

A preferred embodiment of the MEMS device manufacturing method according to the present invention will now be described in detail with reference to the attached drawings. FIG. 1 is a perspective view of a substrate 2 in the condition where a plurality of MEMS devices have not yet been formed thereon. The substrate 2 shown in FIG. 1 is formed from a glass substrate having a thickness of 200 μm, for example. The outer circumference of the substrate 2 is formed with a notch 21 for indicating a reference position. In manufacturing a plurality of MEMS devices by using the substrate 2 formed from a glass substrate shown in FIG. 1, a break start point forming step is first performed to form a break start point in the substrate 2 along the areas corresponding to a plurality of crossing streets set on the substrate 2 before forming a plurality of MEMS devices on the substrate 2.

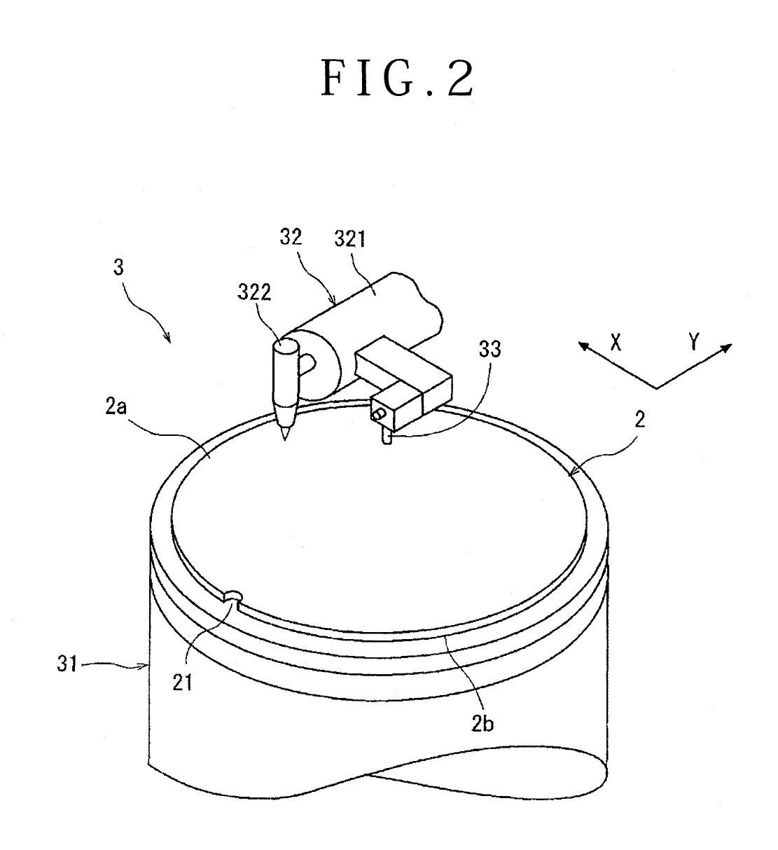

This break start point forming step is performed by using a laser processing apparatus 3 shown in FIG. 2. The laser processing apparatus 3 shown in FIG. 2 includes a chuck table 31 for holding the substrate 2 as a workpiece, laser beam applying means 32 for applying a laser beam to the substrate 2 held on the chuck table 31, and imaging means 33 for imaging the substrate 2 held on the chuck table 31. The chuck table 31 is so configured as to hold the substrate 2 under suction by using suction means. The chuck table 31 is movable by feeding means (not shown) in a feeding direction shown by an arrow X in FIG. 2 and also movable by indexing means (not shown) in an indexing direction shown by an arrow Y in FIG. 2.

The laser beam applying means 32 includes a cylindrical casing 321 extending in a substantially horizontal direction. Although not shown, the casing 321 contains pulsed laser beam oscillating means including a pulsed laser beam oscillator and repetition frequency setting means. The laser beam applying means 32 further includes focusing means 322 mounted on the front end of the casing 321 for focusing the pulsed laser beam oscillated from the pulsed laser beam oscillating means. Although not shown, the laser beam applying means 32 is provided with focal position adjusting means for adjusting the focal position of the pulsed laser beam to be focused by the focusing means 322.

The imaging means 33 is mounted on the front end portion of the casing 321 of the laser beam applying means 32. The imaging means 33 includes illuminating means for illuminating the substrate 2, an optical system for capturing an area illuminated by the illuminating means, and an imaging device (CCD) for imaging the area captured by the optical system. An image signal output from the imaging means 33 is transmitted to control means (not shown). In a memory of the control means, a plurality of coordinate values (set values) for the crossing streets set on the front side of the substrate 2 shown in FIG. 1 are preliminarily stored.

In performing the break start point forming step by using the laser processing apparatus 3 performs to process the break start point along the areas corresponding to the crossing streets set on the substrate 2 before forming a plurality of MEMS device on the substrate 2, the substrate 2 is first placed on the chuck table 31 of the laser processing apparatus 3 shown in FIG. 2 in the condition where one surface of the substrate 2 (the back side 2b of the substrate 2 in this preferred embodiment) comes into contact with the upper surface of the chuck table 31. Thereafter, the suction means is operated to hold the substrate 2 on the chuck table 31 under suction (wafer holding step). Accordingly, the front side 2a of the substrate 2 held on the chuck table 31 is oriented upward.

After performing the wafer holding step mentioned above, the chuck table 31 holding the substrate 2 is moved to a position directly below the imaging means 33 by the feeding means. In the condition where the chuck table 31 is positioned directly below the imaging means 33, an alignment operation is performed by the imaging means 33 and the control means to detect whether or not the substrate 2 is positioned at predetermined coordinate values and then position the substrate 2 at the predetermined coordinate values. More specifically, the imaging means 33 images the notch 21 formed on the outer circumference of the substrate 2 and transmits an image signal corresponding to the notch 21 to the control means. The control means then determines whether or not the notch 21 is positioned at the predetermined coordinate values according to the image signal transmitted from the imaging means 33. If the notch 21 is not positioned at the predetermined coordinate values, the control means controls to rotate the chuck table 31 and then position the notch 21 at the predetermined coordinate values (alignment step).

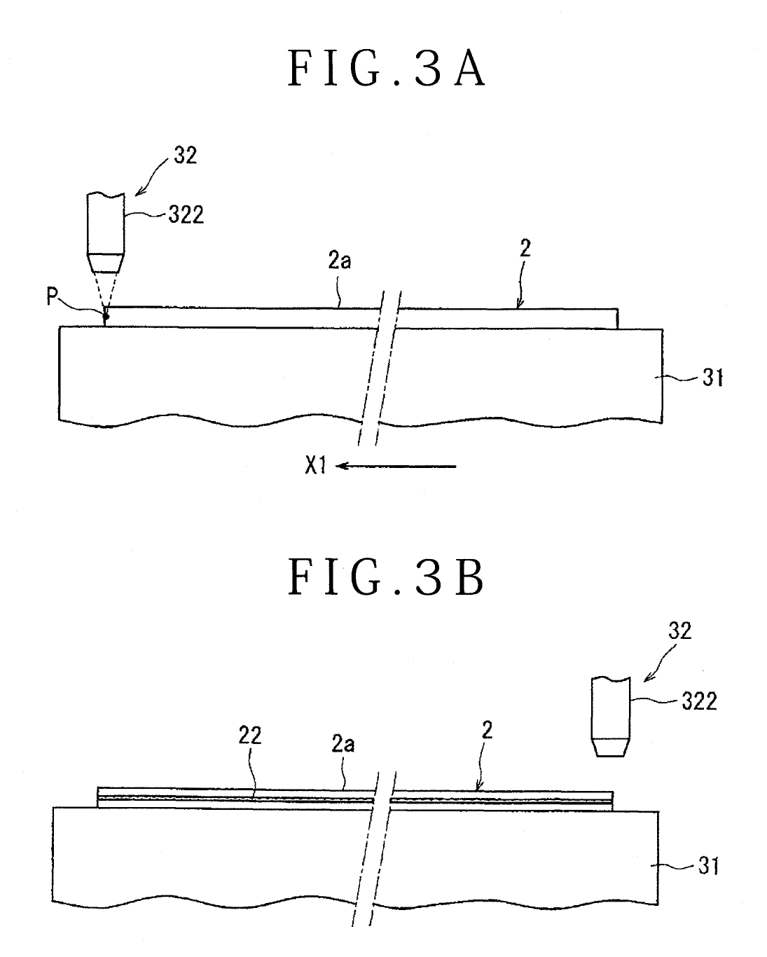

After performing the alignment step mentioned above, the chuck table 31 is moved to a laser beam applying area where the focusing means 322 of the laser beam applying means 32 is located as shown in FIG. 3A, thereby positioning the coordinate values corresponding to one end (left end as viewed in FIG. 3A) of a predetermined one of the street areas set on the substrate 2 directly below the focusing means 322 of the laser beam applying means 32. In this condition, the focal point P of a pulsed laser beam to be applied from the focusing means 322 is adjusted to a middle position in the direction of the thickness of the substrate 2. For example, the focal point P of the pulsed laser beam to be applied from the focusing means 322 may be adjusted to a predetermined position in the following manner. By using a height detecting apparatus for detecting the height of the substrate 2 held on the chuck table 31 as described in Japanese Patent Laid-open No. 2009-63446, the height of the upper surface of the substrate 2 held on the chuck table 31 is detected and the focal position adjusting means (not shown) is operated according to the height of the upper surface of the substrate 2 detected above to thereby adjust the focal point P of the pulsed laser beam to the predetermined position.

Thereafter, a pulsed laser beam having a transmission wavelength to the substrate 2 is applied from the focusing means 322 to the substrate 2, and the chuck table 31 is moved in a feeding direction shown by an arrow X1 in FIG. 3A at a predetermined feed speed. When the coordinate values corresponding to the other end (right end as viewed in FIG. 3B) of the predetermined street area set on the substrate 2 reach the position directly below the focusing means 322 as shown in FIG. 3B, the application of the pulsed laser beam is stopped and the movement of the chuck table 31 is also stopped. As a result, a modified layer 22 as a break start point continuously extending along the predetermined street area is formed inside the substrate 2 as shown in FIG. 3B (modified layer forming step). This modified layer forming step is performed along the areas corresponding to all of the crossing streets set on the substrate 2.

For example, the modified layer forming step mentioned above is performed under the following processing conditions.

| Light source | LD pumped Q-switched Nd | |
|---|---|---|
| | YVO4 pulsed laser | |
| Wavelength | 1064 | nm |
| Repetition frequency | 80 | kHz |
| Average power | 0.2 | W |
| Focused spot diameter | φ 1 | μm |
| Work feed speed | 200 | mm/sec |

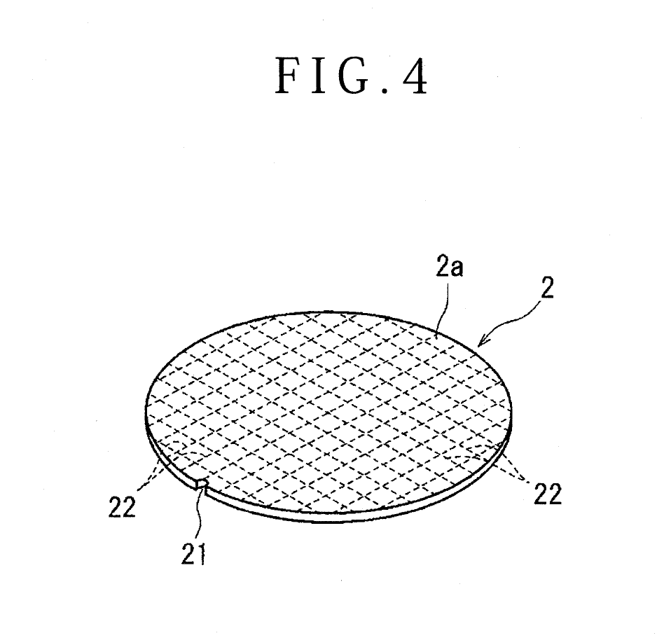

As described above, the modified layer forming step as a preferred embodiment of the break start point forming step is performed along the areas corresponding to all of the crossing streets set on the substrate 2, thereby forming the modified layers 22 along the areas corresponding to all of the crossing streets inside the substrate 2 as shown in FIG. 4. In this manner, the modified layer forming step as a preferred embodiment of the break start point forming step is performed for the substrate 2 before forming a plurality of MEMS devices on the substrate 2. Accordingly, it is possible to eliminate the problem that the quality of the MEMS devices may be reduced due to the influence of heat by the application of the laser beam.

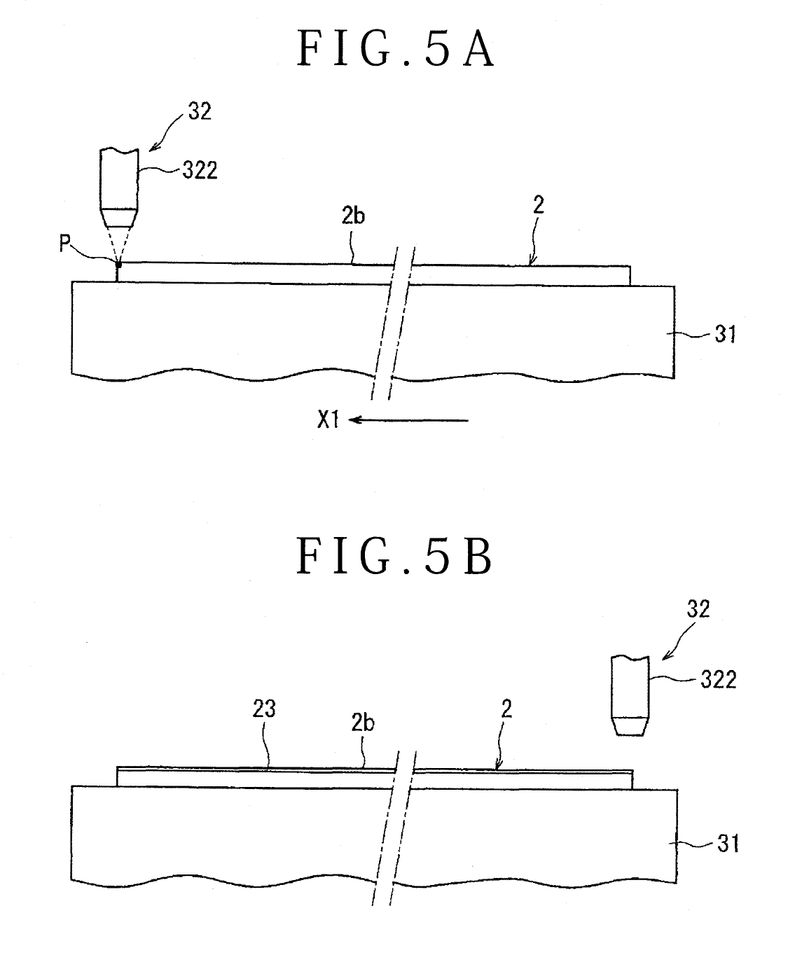

Another preferred embodiment of the break start point forming step will now be described with reference to FIGS. 5A and 5B. In the preferred embodiment of the break start point forming step shown in FIGS. 5A and 5B, a laser processing apparatus substantially the same as the laser processing apparatus 3 shown in FIG. 2 is used. Accordingly, the same parts as those of the laser processing apparatus 3 are denoted by the same reference numerals in FIGS. 5A and 5B. In performing this preferred embodiment of the break start point forming step, the substrate 2 is first placed on the chuck table 31 in the condition where the front side 2a of the substrate 2 comes into contact with the upper surface of the chuck table 31. Thereafter, the suction means is operated to hold the substrate 2 on the chuck table 31 under suction (wafer holding step). Accordingly, the back side 2b of the substrate 2 held on the chuck table 31 is oriented upward.

After performing the wafer holding step mentioned above, the alignment step mentioned above is performed. Thereafter, the chuck table 31 is moved to the laser beam applying area where the focusing means 322 of the laser beam applying means 32 is located as shown in FIG. 5A, thereby positioning the coordinate values corresponding to one end (left end as viewed in FIG. 5A) of the predetermined street area directly below the focusing means 322 of the laser beam applying means 32. In this condition, the focal point P of a pulsed laser beam to be applied from the focusing means 322 is adjusted to a position on the upper surface (back side 2b) of the substrate 2. Thereafter, a pulsed laser beam having an absorption wavelength to the substrate 2 is applied from the focusing means 322 to the substrate 2, and the chuck table 31 is moved in a feeding direction shown by an arrow X1 in FIG. 5A at a predetermined feed speed. When the coordinate values corresponding to the other end (right end as viewed in FIG. 5B) of the predetermined street area set on the substrate 2 reach the position directly below the focusing means 322 as shown in FIG. 5B, the application of the pulsed laser beam is stopped and the movement of the chuck table 31 is also stopped. As a result, a laser processed groove 23 as a break start point continuously extending along the predetermined street area is formed on the upper surface of the substrate 2 as shown in FIG. 5B (laser processed groove forming step). This laser processed groove forming step is performed along the areas corresponding to all of the crossing streets set on the substrate 2.

For example, the laser processed groove forming step mentioned above is performed under the following processing conditions.

| Light source | LD pumped Q-switched Nd | |
|---|---|---|
| | YVO4 pulsed laser | |
| Wavelength | 355 nm (third-harmonic | |
| | generation of YVO4 pulsed laser) | |
| Repetition frequency | 100 | kHz |
| Average power | 0.5 | W |
| Focused spot diameter | φ 10 | μm |
| Work feed speed | 300 | mm/sec |

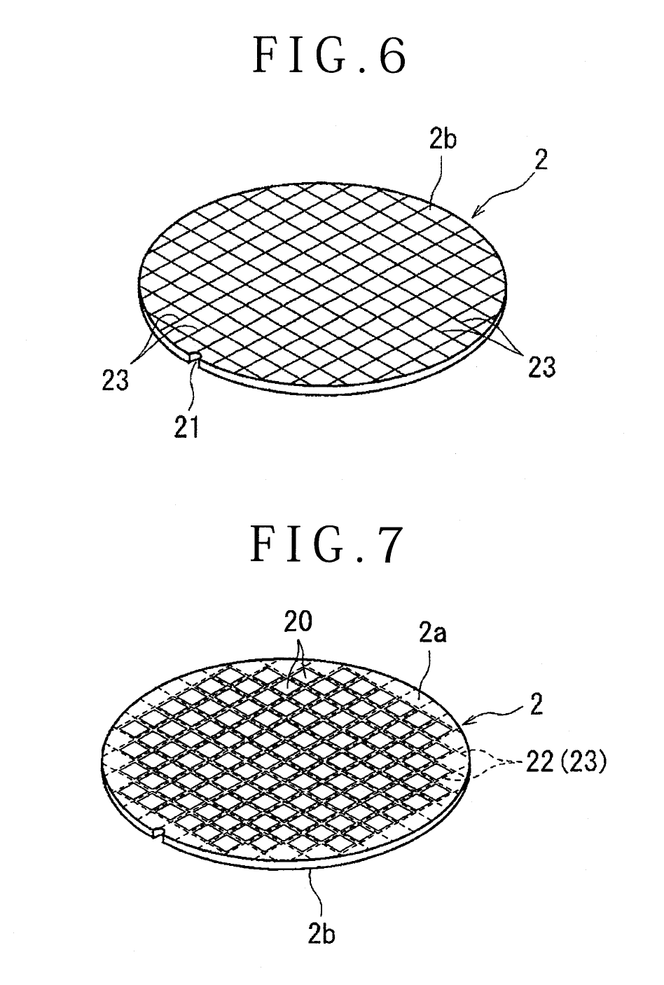

As described above, the laser processed groove forming step as another preferred embodiment of the break start point forming step is performed along the areas corresponding to all of the crossing streets set on the substrate 2, thereby forming the laser processed grooves 23 along the areas corresponding to all of the crossing streets on the back side 2b of the substrate 2 as shown in FIG. 6. In this manner, the laser processed groove forming step as another preferred embodiment of the break start point forming step is performed for the substrate 2 before forming a plurality of MEMS devices on the substrate 2. Accordingly, it is possible to eliminate the problem that the quality of the MEMS devices may be reduced due to the deposition of debris scattered by the application of the laser beam.

After performing the break start point forming step mentioned above, a device forming step is performed to form a plurality of MEMS devices in a plurality of areas partitioned by the crossing street areas on the front side 2a of the substrate 2. For example, this device forming step may be performed by the method disclosed in Japanese Patent Laid-open No. 2005-293918. As described above, the device forming step is performed to form a plurality of MEMS devices 20 in a plurality of areas partitioned by the crossing street areas on the front side 2a of the substrate 2 as shown in FIG. 7.

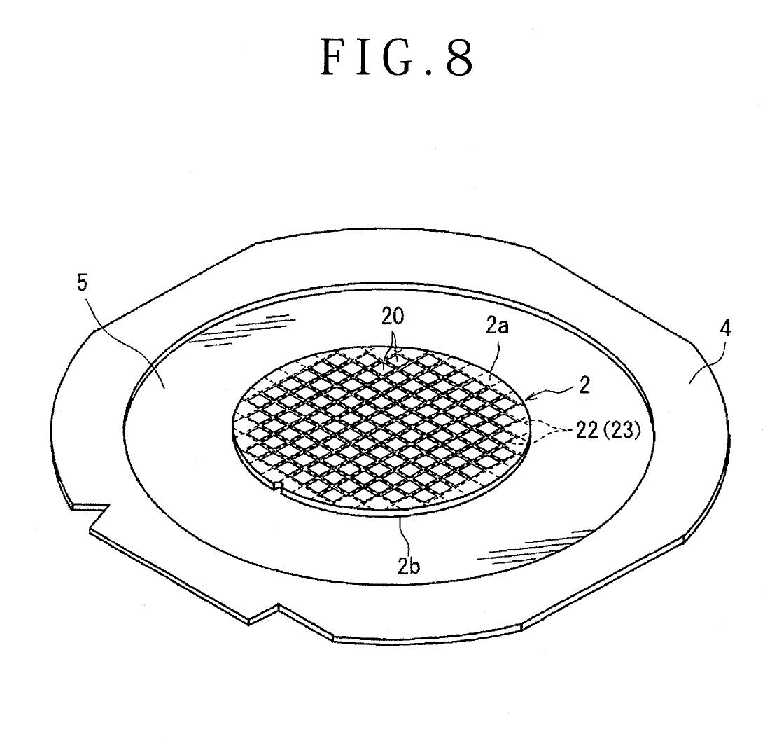

After performing the device forming step mentioned above, a substrate supporting step is performed in such a manner that the substrate 2 having the MEMS devices 20 on the front side 2a is attached to a dicing tape 5 supported to an annular frame 4 as shown in FIG. 8. More specifically, the dicing tape 5 is preliminarily supported at its outer circumferential portion to the annular frame 4 so as to close the inner opening of the annular frame 4. The back side 2b of the substrate 2 is attached to the front side of the dicing tape 5.

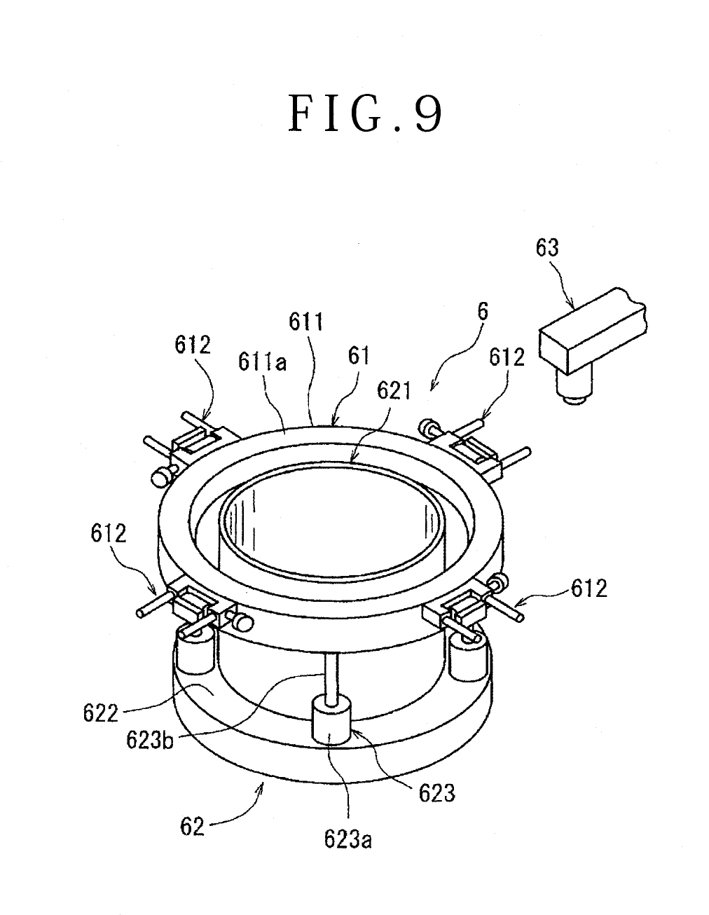

Thereafter, a substrate breaking step is performed in such a manner that an external force is applied to the substrate 2 supported through the dicing tape 5 to the annular frame 4 to thereby break the substrate 2 along the street areas where the modified layers 22 or the laser processed grooves 23 as the break start point are formed, thus dividing the substrate 2 into the individual MEMS devices 20. This substrate breaking step is performed by using a tape expanding apparatus 6 shown in FIG. 9. The tape expanding apparatus 6 shown in FIG. 9 includes frame holding means 61 for holding the annular frame 4, tape expanding means 62 for expanding the dicing tape 5 supported to the annular frame 4 held by the frame holding means 61, and a pickup collet 63. The frame holding means 61 includes an annular frame holding member 611 and a plurality of clamps 612 as fixing means provided on the outer circumference of the frame holding member 611. The upper surface of the frame holding member 611 functions as a mounting surface 611a for mounting the annular frame 4 thereon. The annular frame 4 mounted on the mounting surface 611a is fixed to the frame holding member 611 by the clamps 612. The frame holding means 61 is supported by the tape expanding means 62 so as to be vertically movable.

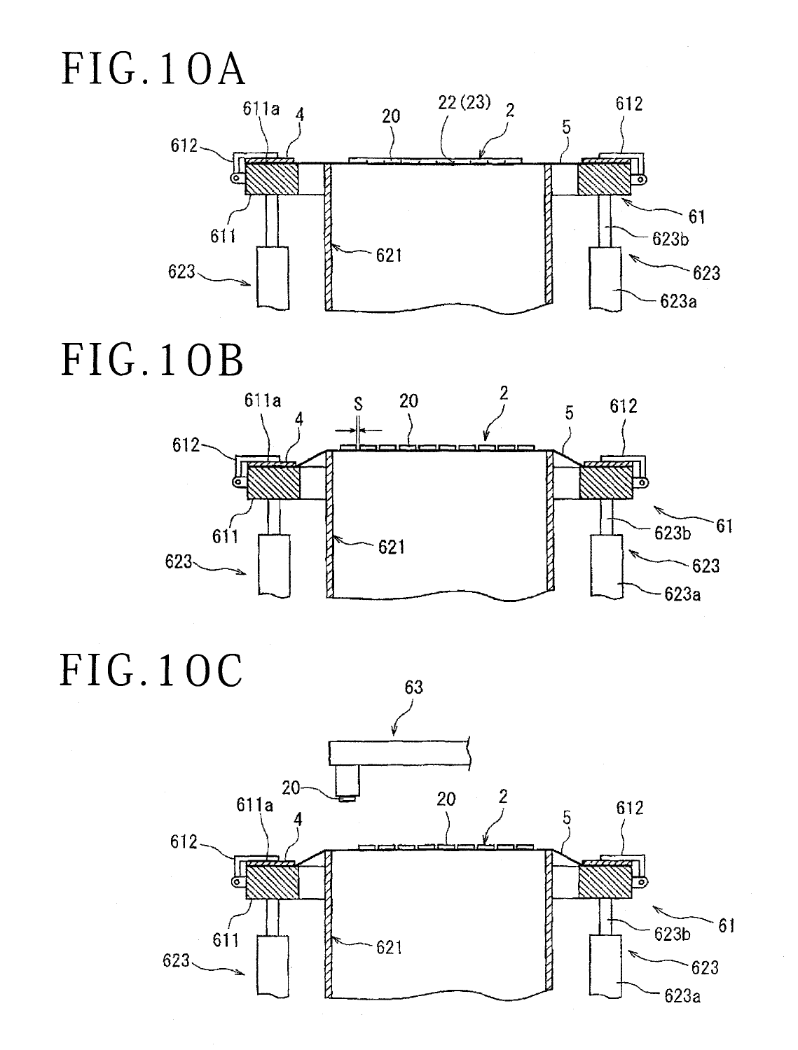

The tape expanding means 62 includes an expanding drum 621 provided inside of the annular frame holding member 611. The expanding drum 621 has an outer diameter smaller than the inner diameter of the annular frame 4 and an inner diameter larger than the outer diameter of the substrate 2 attached to the dicing tape 5 supported to the annular frame 4. The expanding drum 621 has a supporting flange 622 at the lower end of the drum 621. The tape expanding means 62 further includes supporting means 623 for vertically movably supporting the annular frame holding member 611. The supporting means 623 is composed of a plurality of air cylinders 623a provided on the supporting flange 622. Each air cylinder 623a is provided with a piston rod 623b connected to the lower surface of the annular frame holding member 611. The supporting means 623 composed of these plural air cylinders 623a functions to vertically move the annular frame holding member 611 so as to selectively take a reference position where the mounting surface 611a is substantially equal in height to the upper end of the expanding drum 621 as shown in FIG. 10A and an expansion position where the mounting surface 611a is lower in height than the upper end of the expanding drum 621 by a predetermined amount as shown in FIG. 10B.

The substrate breaking step and a pickup step using the tape expanding apparatus 6 will now be described with reference to FIGS. 10A to 10C. As shown in FIG. 10A, the annular frame 4 supporting the substrate 2 through the dicing tape 5 is mounted on the mounting surface 611a of the frame holding member 611 of the frame holding means 61 and fixed to the frame holding member 611 by the clamps 612 (frame holding step). At this time, the frame holding member 611 is set at the reference position shown in FIG. 10A. Thereafter, the air cylinders 623a as the supporting means 623 of the tape expanding means 62 are operated to lower the frame holding member 611 to the expansion position shown in FIG. 10B. Accordingly, the annular frame 4 fixed to the mounting surface 611a of the frame holding member 611 is also lowered, so that the dicing tape 5 supported to the annular frame 4 comes into abutment against the upper end of the expanding drum 621 and is expanded as shown in FIG. 10B (tape expanding step).

As a result, a tensile force acts on the substrate 2 attached to the dicing tape 5 in the radial direction of the substrate 2. As described above, the substrate 2 is formed with the modified layers 22 or the laser processed grooves 23 extending along the areas corresponding to the crossing streets set on the substrate 2. Accordingly, when the tensile force acts on the substrate 2 in its radial direction, the substrate 2 is broken along the areas corresponding to the crossing streets from the modified layers 22 or the laser processed grooves 23 as the break start point (breaking step). By performing this breaking step, a spacing S is formed between any adjacent ones of the individual MEMS devices 20 divided from each other.

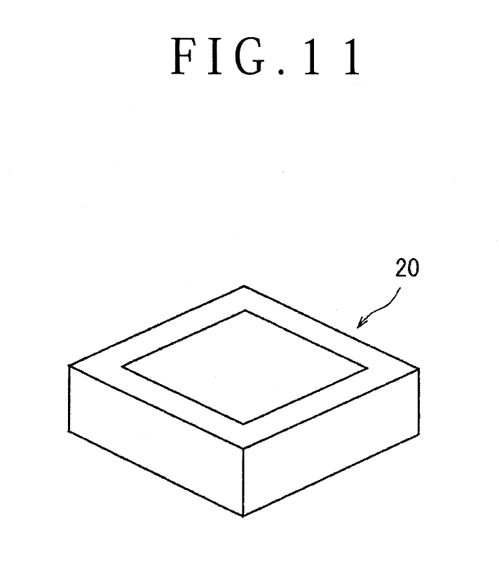

Thereafter, as shown in FIG. 10C, the pickup collet 63 is operated to hold each MEMS device 20 under suction and peel it off from the dicing tape 5, thus individually picking up the MEMS devices 20. As a result, each MEMS device 20 shown in FIG. 11 is obtained. In this pickup step, the spacing S is formed between any adjacent ones of the individual MEMS devices 20 attached to the dicing tape 5, so that each MEMS device 20 can be easily picked up without the contact with its adjacent MEMS device 20.

While the specific preferred embodiment of the present invention has been described above, it should be noted that the present invention is not limited to the above preferred embodiment, but various modifications may be made without departing from the scope of the present invention. In the above preferred embodiment, the break start point forming step is provided by the method of applying a laser beam to the substrate 2 along the areas corresponding to the crossing streets set on the substrate 2 before forming the MEMS devices 20 on the substrate 2, thereby forming the modified layers 22 inside the substrate 2 or the laser processed grooves 23 on the back side 2b of the substrate 2. As a modification, scribe grooves as a break start point may be formed on the back side of the substrate along the areas corresponding to the crossing streets by using a diamond scriber.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A MEMS device manufacturing method comprising:
a break start point forming step of forming a break start point in a substrate along the areas corresponding to a plurality of crossing streets set on said substrate before forming a plurality of MEMS devices on said substrate;
a device forming step of forming said MEMS devices in a plurality of areas partitioned by said areas corresponding to said crossing streets on the front side of said substrate after performing said break start point forming step; and
a substrate breaking step of applying an external force to said substrate after performing said device forming step to thereby break said substrate along said areas corresponding to said crossing streets where said break start point is formed, thus dividing said substrate into said individual MEMS devices.

2. The MEMS device manufacturing method according to claim 1, wherein said substrate includes a glass substrate.

3. The MEMS device manufacturing method according to claim 1, wherein said break start point forming step includes the step of applying a laser beam having a transmission wavelength to said substrate along said areas corresponding to said crossing streets in the condition where the focal point of said laser beam is set inside said substrate, thereby forming a plurality of modified layers as said break start point inside said substrate along said areas corresponding to said crossing streets.
